(19) United States
(12) Patent Application Publication
(10) Pub. No.: US 2009/0097205 A1
(43) Pub. Date: Apr. 16, 2009

(54) ELECTRONIC EQUIPMENT SYSTEM

(75) Inventors: Hitoshi Matsushima, Ryugasaki (JP); Hiroshi Fukuda, Odawara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/193,100

(22) Filed: Aug. 18, 2008

(30) Foreign Application Priority Data
Oct. 16, 2007 (JP) 2007-268496

(51) Int. Cl. H05K 7/20

(52) U.S. Cl. 361/700

(57) ABSTRACT

In a space of a data center or the like where many disk array apparatuses and electronic equipment systems are arranged, it is an object of the present invention to reduce the energy required for cooling the apparatus itself and cooling the space. In electronic equipment having heat generating elements such as a disk array apparatus or CPU, low-temperature waste heat exhausted from the equipment is heated through a vapor compression cycle once and then recovered as cold water through an absorption refrigeration cycle. In the space of a data center or the like where many disk array apparatuses and electronic equipment systems are arranged, this can reduce the energy required for cooling the apparatus itself and cooling the space, drastically improve the processing speed and reliability of the apparatus/system and realize capacity and speed enhancements.

### BACKGROUND OF THE INVENTION

The present invention relates to an electronic equipment system.

A disk array apparatus is configured with many magnetic or optical disk drives mounted in a housing to improve data saving reliability. These disk array apparatuses are connected via a high-speed dedicated network channels such as optical network channels, operated by management software and used as a SAN (storage area network), NAS (network attached storage) or an independent RAID (Redundant Array of Inexpensive Disks) disk apparatus.

Main heat sources for disk drives mounted in these disk array apparatuses are control electronic parts such as a drive motor, actuator and LSI. The heat generated from these heat sources is cooled by cooing air supplied from outside the housing by a cooling fan installed in the disk array housing. When the cooling performance is poor, the temperature of the disk drive rises, raising concerns about malfunction or long-term reliability of control electronic parts.

Furthermore, a great quantity of heat is also produced in a controller which controls exchange of data between an outside control apparatus and the disk drive. When the cooling performance of this controller is poor, the temperature of the controller rises, likewise raising concerns about malfunction or damage to elements.

On the other hand, a reduction of noise outputted from the fan for driving the air flow in the disk array apparatus is also an important issue and the amount of air flow necessary for cooling may not be secured sufficiently when the generation of noise is taken into consideration.

In this way, the disk array apparatus has the problems with satisfactory cooling of each heat generating member and noise reduction of the apparatus.

Due to the widespread use of a blade server and introduction of a large-scale storage accompanying a drastic increase in the amount of data, a drastic increase of power consumption is becoming a critical requirement for data center operations. For example, the amount of heat generation from servers is increasing at a rate of 20 to 25% a year and is estimated to be on the order of 20 KW per housing a few years later. For this reason, the ratio of power consumption of a server to power consumption required for cooling the server which is currently 1:1 is estimated to become 1:1.5 to 2.0 in the future and power required for cooling is becoming a bottleneck.

Against such a background, electric power conditions at data centers currently concentrated on big cities are becoming stringent and coping with restrictions on space, power consumption and cooling performance is becoming an important issue from the standpoint of construction of a data center architecture. In this respect, there is also an effort afoot to tighten regulatory control over the energy efficiency of data centers in the United States and there is a drastically growing demand from users for all data centers to introduce, operate and manage IT equipment using power saving techniques.

Thus, performance of servers and storages has been significantly improved in these years, but power consumption has also drastically increased accordingly. The power is eventually converted to heat and accumulated in the housing. Therefore, the reduction of power consumption and heat control measures are issues to be addressed together and it is important how to overcome this problem.

As a means of solving such problems, conventional data centers adopt, for example, a system that monitors an air flow and also controls cooing in the data centers according to the detected air flow to improve cooling efficiency (see JP-A-2006-208000). Furthermore, there is also an example of electronic equipment that combines compression refrigeration and absorption refrigeration from the standpoint of securing high cooling performance (see JP-A-11-223412).

### BRIEF SUMMARY OF THE INVENTION

The prior art described in JP-A-2006-208000 shows a method of controlling a refrigerator for cooling, yet does not disclose any solution for improving the efficiency of the refrigerator itself. On the other hand, the prior art described in JP-A-11-223412 is designed to guide a liquid refrigerant from a heat exchanger on a heat source side of a compression refrigeration system to an evaporator of an absorption refrigeration system and realize supercooling using heat of evaporation from the evaporator.

This improves cycle efficiency of the compression refrigeration system, but these systems use waste heat as high as approximately 200° C. generated from a drive source accompanying combustion such as an engine and turbine as the heat source of the absorption refrigeration system and do not function as the systems using low-temperature waste heat of 50, 60° C. exhausted from electronic apparatuses.

It is an object of the present invention to provide a disk array apparatus and electronic equipment system capable of reducing energy for cooling the apparatus itself and cooling space, drastically improving the processing speed and reliability of the apparatus/system and realizing capacity and speed enhancements.

The above object can be achieved by an electronic equipment system having a plurality of disk drives accommodated in a housing, a controller that controls these disk drives and an element that makes up the controller and generates heat, wherein the system is provided with a refrigeration cycle for causing the temperature of the heat of the element to rise and an absorption refrigeration cycle for recovering the temperature-risen waste heat using a hot water tank.

Furthermore, the above object can be achieved by the refrigeration cycle including pipes or the like connecting a compressor, a radiator, an expansion valve and an evaporator, and cooling warm air exhausted from the electronic equipment through the evaporator.

Furthermore, the above object can be achieved by the radiator in the absorption refrigeration cycle being thermally connected to the hot water tank.

Furthermore, the above object can be achieved by the hot water tank being connected to the absorption refrigerator for waste heat recovery.

Furthermore, the above object can be achieved by the absorption refrigerator for waste heat recovery supplying cold water to a building where the disk array apparatus or the electronic equipment is installed.

Furthermore, the above object can be achieved by a disk array apparatus having a controller that accommodates many disk drives and controls the disk drive group or electronic equipment including a heat generating element such as a CPU, wherein low-temperature waste heat generated from the electronic equipment is recovered as hot water through a vapor compression cycle using the waste heat as a heat source on the low-temperature side and this hot water is used as a heat source of a waste heat recovery type absorption refrigeration cycle.

Furthermore, the above object can be achieved by a disk array apparatus having a controller that accommodates many disk drives and controls the disk drive group or electronic equipment including a heat generating element such as a CPU, including a back door with the air source evaporator incorporated on the housing exhaust side of the electronic equipment and a front door with the air source water heat exchanger incorporated on the housing intake side of the electronic equipment.

According to the present invention, it is possible to provide a disk array apparatus and electronic equipment system capable of reducing the energy required to cool the apparatus itself and cool the space, drastically improving the processing speed and reliability of the apparatus/system and realizing capacity and speed enhancements.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1 is a configuration diagram of a disk array apparatus and electronic equipment system provided with a first embodiment of the present invention;

FIG. 2 is a perspective view of the disk array apparatus and electronic equipment provided with the first embodiment of the present invention;

FIG. 3 is a configuration diagram of a disk array apparatus and electronic equipment system provided with a second embodiment of the present invention;

FIG. 4 is a configuration diagram of a disk array apparatus and electronic equipment system provided with a third embodiment of the present invention;

FIG. 5 is a perspective view of the disk array apparatus and electronic equipment provided with the third embodiment of the present invention; and

FIG. 6 is a configuration diagram of a disk array apparatus and electronic equipment system provided with a fourth embodiment of the present invention.

### DETAILED DESCRIPTION OF THE INVENTION

Before explaining embodiments of the present invention, principles of an absorption refrigerator will be explained briefly.

When a tube through which water is flowing is passed through a vacuum chamber containing water (refrigerant) and water (refrigerant) is sprayed over the tube using a pump, the water (refrigerant) deprives the water in the tube of heat of evaporation at 3 to 4° C. and evaporates, and the water in the tube is thereby cooled. This water can be used for cooling.

Here, an aqueous solution of lithium bromide has a characteristic that when the temperature is the same, the higher the concentration, the lower the pressure becomes, and when the concentration is the same, the lower the temperature, the lower the pressure becomes, and therefore when lithium bromide is contained in a vacuum chamber and an aqueous solution of lithium bromide is sprayed over a tube through which water is flowing likewise, the water is absorbed by the aqueous solution of lithium bromide.

However, when the absorption of water from the evaporator continues, the aqueous solution of lithium bromide becomes more diluted, and so the absorption cannot be continued endlessly. Therefore, vapor is separated by heating the diluted aqueous solution of lithium bromide, the absorption performance is recovered again and the evaporator can continue evaporation of the refrigerant endlessly, and so the chiller water can also be obtained continuously.

In this way, the absorption refrigerator can be operated when a predetermined temperature at which the aqueous solution of lithium bromide can be heated can be obtained continuously. Generally, absorption refrigerators use hot water of approximately 90 to 100° C. to create chiller water of approximately 12° C. which is then used for air conditioning of buildings or the like.

Therefore, the present inventor thought of using waste heat of a disk array apparatus that always produces waste heat of 50° C. to 60° C. as a heat source of an absorption refrigerator, and as a result came up with complementing a temperature short of 90° C. to 100° C. which is necessary for the absorption refrigerator with waste heat of a vapor compression cycle.

Hereinafter, embodiments of the present invention will be explained according to the accompanying drawings.

### Embodiment 1

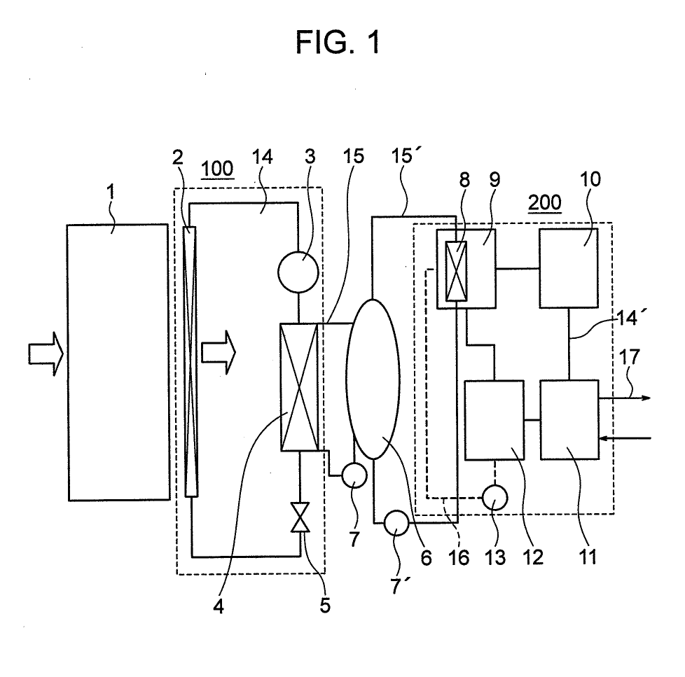

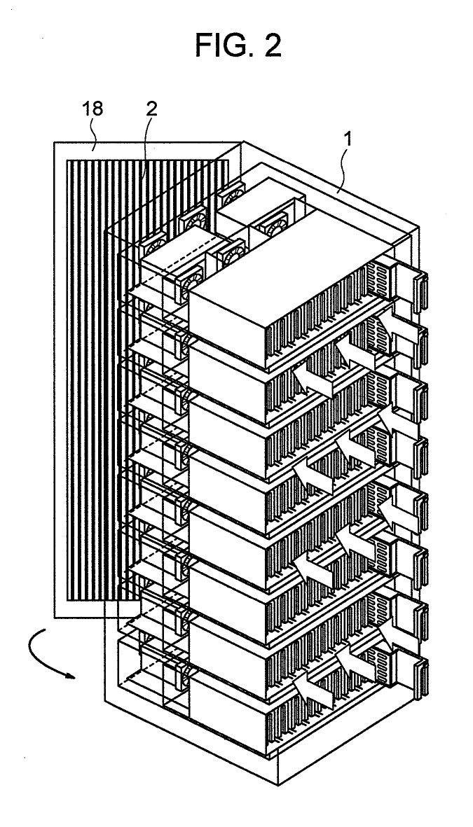

A first embodiment of the present invention will be shown in FIG. 1 and FIG. 2.

FIG. 1 is a configuration diagram of a disk array apparatus and electronic equipment system according to a first embodiment.

FIG. 2 is a perspective view of the disk array apparatus and electronic equipment provided with the first embodiment.

As shown in the figures, the disk array apparatus and electronic equipment system are constructed of an apparatus housing 1 which is a disk array apparatus or electronic equipment, a vapor compression cycle 100, a hot water tank 6 and an absorption cycle 200 or the like.

The vapor compression cycle 100 is constructed of an air source evaporator 2, a compressor 3, a water heat source condenser 4, an expansion valve 5 and a refrigerant line 14 which connects these components or the like. This vapor compression cycle 100 is called a “refrigeration cycle” and refers to a general, so-called refrigeration cycle which is introduced into a home room air-conditioner or the like.

Chlorofluorocarbon alternatives such as R410A or natural refrigerant such as CO₂ are used as a refrigerant. Furthermore, the absorption cycle 200 is constructed of a generator 9, a condenser 10, an evaporator 11, an absorber 12, a solution pump 13, and a refrigerant line 14′ and solution line 16 that connect these components or the like. A natural refrigerant such as water is used as a refrigerant and lithium bromide or the aforementioned aqueous solution of lithium bromide or the like is used as a solution. According to this embodiment, the vapor compression cycle 100, hot water tank 6 and absorption cycle 200 are installed as separate units in the vicinity of the apparatus housing 1.

In FIG. 1, cooling air driven by a fan (not shown) inside the apparatus housing 1 flows into the apparatus housing 1, cools each heat generating component and is then exhausted from behind the apparatus housing 1. This is because when an electronic apparatus is mounted in a 19-inch standard rack, the wiring space of the rack is normally used as an exhaust area of the entire rack.

In FIG. 2, the apparatus housing 1 is constructed of a plurality of disk array apparatuses or electronic equipment units mounted in the 19-inch standard rack. In this embodiment, a back door 18 with the air source evaporator 2 incorporated is provided on the exhaust side of the apparatus housing 1. Heat of approximately 40° C. to 50° C. produced from the disk array apparatus or electronic equipment is exhausted from behind the apparatus housing 1.

In the vapor compression cycle 100 shown in FIG. 1, a high-temperature, high-pressure refrigerant gas is liquefied by the water heat source condenser 4 through revolutions of the compressor 3, passed through the expansion valve 5, thereby pressure-reduced and evaporated through the air source evaporator 2. Therefore, this 40° C. to 50° C. waste heat is received by the air source evaporator 2 attached to the back door 18 and the vapor compression cycle 100 shown in FIG. 1 is thereby operated. This causes the 40° C. to 50° C. exhaust air exhausted from the apparatus housing 1 to be cooled by the vapor compression cycle 100 and cooled down to the order of a room temperature of a room (data center room) where the disk array apparatus or electronic equipment is installed and emitted into the ambient air.

Therefore, combining the apparatus housing 1 and the vapor compression cycle 100 can drastically reduce the load on the air conditioner for cooling waste heat from the apparatus housing 1 which is conventionally required or omit the air conditioner. This is especially effective in reducing the load on the air conditioner when many apparatus housings 1 are densely installed as in the case of a data center.

On the other hand, in the vapor compression cycle 100, the refrigeration cycle operates using waste heat of 40° C. to 50° C. of the apparatus housing 1 as the heat source on the low-temperature side as described above and heat resulting from adding heat generated from the compressor 3 to the absorbed heat (cooled heat) from the waste heat from the air source evaporator 2 is emitted to the water side of the water heat source condenser 4.

This causes the temperature of the water side to rise to around 90° C. at the outlet of the water heat source condenser 4. Therefore, this embodiment combines the water heat source condenser 4 with the absorption cycle 200.

That is, connecting the hot water tank 6 of the absorption cycle 200 and the water heat source condenser 4 using the water pipe 15 allows the hot water tank 6 to make hot water with heat around 90° C. On the water pipe 15 side, water is circulating in the water heat source condenser 4 by the function of a hot water pump 7 and hot water at a high temperature obtained from the water heat source condenser 4 is stored in the hot water tank 6.

According to this embodiment, hot water around 90° C. stored in the hot water tank 6 can be guided to the generator 9 of the absorption cycle 200 using a hot water pump 7′ on a water pipe 15′ side and this hot water can be used as a heat source to operate the absorption cycle 200 and generate cold water. Vapor is generated in the generator 9 by a water/solution heat exchanger 8 installed in the generator 9. This vapor is converted to liquid in the condenser 10, and then evaporated at the evaporator 11 to generate cold water. The cold water generated can be transported to locations requiring cold water via a cold water pipe 17 and can be used, for example, for air conditioning of the data center (living room) where the disk array apparatus or data center electronic equipment explained in this embodiment is accommodated.

Thus, according to this embodiment, assuming the amount of heat generated of the conventional apparatus housing 1 is 1.0, electric power of the air conditioner necessary for cooling this heat is 0.33 when a COP of the air conditioner is on the order of general 3.0 and the total power of the apparatus housing 1 and air conditioner is 1.33. When drive power for a fan to transport the exhaust gas to the air conditioner, a cooling tower installed outside the room for cooling the air conditioner and a supplementary machine thereof is added to this, power including that for cooling reaches 1.7 to 1.9 with respect to the amount of heat generated of 1.0 of the apparatus housing 1 and the corresponding energy is wasted without being reused.

On the other hand, according to this embodiment, assuming the COP of the vapor compression cycle 100 is on the order of 3.0, the total power of the apparatus housing 1 and vapor compression cycle 100 is 1.33. Here, if the COP of the absorption cycle 200 is on the order of 0.75, 1.0 out of 1.33 of the total power of the apparatus housing 1 and vapor compression cycle 100 is recovered as cold water and the energy not reused remains at 0.53 when the amount of power consumed in other supplementary machines is assumed to be 0.2.

The conventional absorption cycle 200 does not sufficiently function as a refrigerator at a temperature of 100° C. or below, but research and development of the waste heat recovery type absorption cycle 200 is underway in these years and one that functions even at 90° C. or below is making its appearance and further improvement of efficiency is expected.

In this way, the present invention can recover waste heat of 50, 60° C. exhausted from electronic apparatuses that would not be conventionally used, and can thereby drastically improve the energy efficiency.

### Embodiment 2

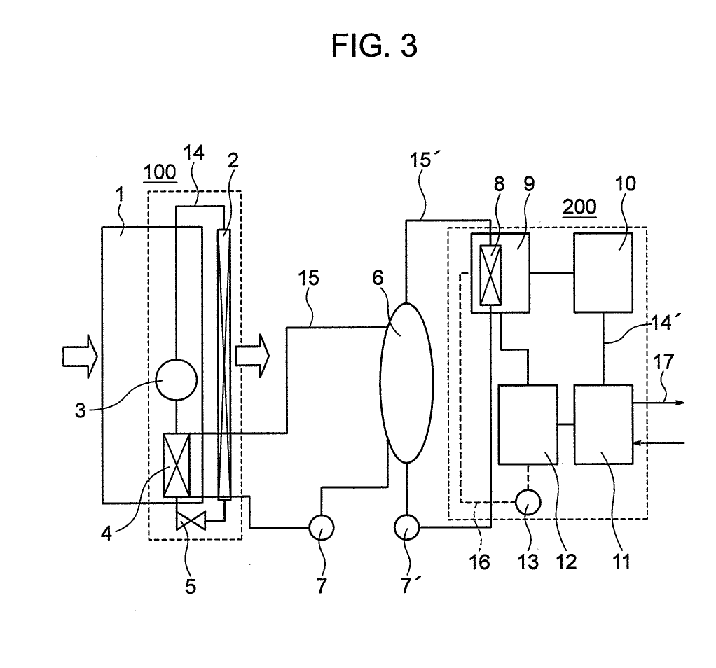

A second embodiment of the present invention will be shown in FIG. 3.

FIG. 3 is a configuration diagram of a disk array apparatus and electronic equipment system of this embodiment.

In FIG. 3, the disk array apparatus and electronic equipment system are constructed of an apparatus housing 1 which is the disk array apparatus or electronic equipment, a vapor compression cycle 100, a hot water tank 6 and an absorption cycle 200 or the like. The vapor compression cycle 100 is constructed of an air source evaporator 2, a compressor 3, a water heat source condenser 4, an expansion valve 5 and a refrigerant line 14 that connects these components or the like. Chlorofluorocarbon alternatives such as R410A or a natural refrigerant such as CO₂ are used as a refrigerant. Furthermore, the absorption cycle 200 is constructed of a generator 9, a condenser 10, an evaporator 11, an absorber 12, a solution pump 13 and a refrigerant line 14′ and a solution line 16 that connect these components or the like. A natural refrigerant such as water is used as a refrigerant and lithium bromide or the like is used as a solution.

In FIG. 3, cooling air driven by a fan (not shown) located in the apparatus housing 1 flows into the apparatus housing 1, cools down each heat generating part and is then exhausted from behind the apparatus housing 1. This is because when the electronic apparatus is mounted in a 19-inch standard rack, the wiring space of the rack is normally used as an exhaust area of the entire rack.

In the disk array apparatus and electronic equipment of this embodiment, the apparatus housing 1 is constructed of a plurality of disk array apparatuses or electronic equipment units mounted in a 19-inch standard rack. In this embodiment as well as the first embodiment, a back door 18 incorporating the air source evaporator 2 is provided on the exhaust side of the apparatus housing 1 and the compressor 3, water heat source condenser 4 and expansion valve 5 or the like are further incorporated in the apparatus housing 1. In this embodiment, the hot water tank 6 and absorption cycle 200 are installed as separate units in the vicinity of the apparatus housing 1.

In this embodiment, the vapor compression cycle 100 is operated using waste heat of 40 to 50° C. exhausted from behind the aforementioned apparatus housing 1 as a heat source on the low-temperature side. This causes the exhaust air from the apparatus housing 1 to be cooled down to the order of room temperature and emitted into the ambient air. This can drastically reduce the load on the air conditioner for cooling waste heat from the apparatus housing 1 which is conventionally required or omit the air conditioner. This is especially effective in reducing the load on an air conditioner when many apparatus housings 1 are densely installed as in the case of a data center.

On the other hand, in the vapor compression cycle 100, the refrigeration cycle operates using waste heat of 40° C. to 50° C. of the apparatus housing 1 as a heat source on the low-temperature side as described above, and heat resulting from adding the heat generated from the compressor 3 to the absorbed heat (cooled heat) from the waste heat from the air source evaporator 2 is emitted to the water side of the water heat source condenser 4. This causes the temperature on the water side to rise to around 90° C. at the outlet of the water heat source condenser 4. Hot water is circulating on a water pipe 15 side through the function of a hot water pump 7 and high-temperature hot water acquired by the water heat source condenser 4 is stored in the hot water tank 6.

The present invention recovers the energy of hot water stored in the hot water tank 6 to realize energy saving for the entire system. That is, hot water at around 90° C. stored in the hot water tank 6 is guided to the generator 9 of the absorption cycle 200 using a hot water pump 7′ on a water pipe 15′ side and the absorption cycle 200 is operated using this as a heat source to produce cold water.

In this embodiment, vapor is generated from the generator 9 through a water/solution heat exchanger 8 installed in the generator 9. Vapor is converted to liquid in the condenser 10 and then evaporated at the evaporator 11 to generate cold water. The cold water generated can be transported to locations requiring cold water via a cold water pipe 17.

Thus, the present invention can recover waste heat of 50 to 60° C. exhausted from the electronic apparatus or the like which is not conventionally used, and can thereby drastically improve the energy efficiency as the system.

### Embodiment 3

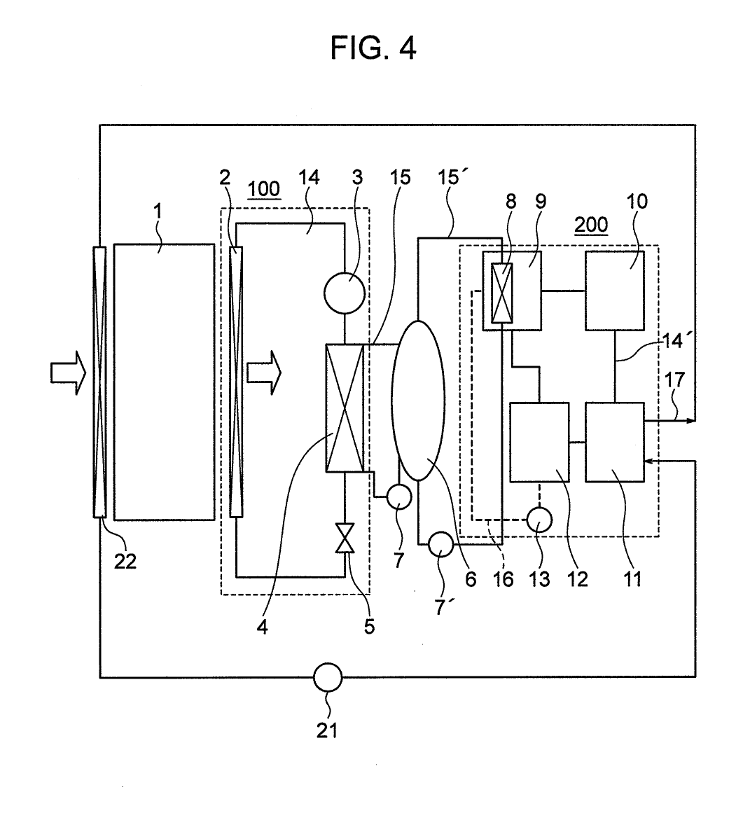

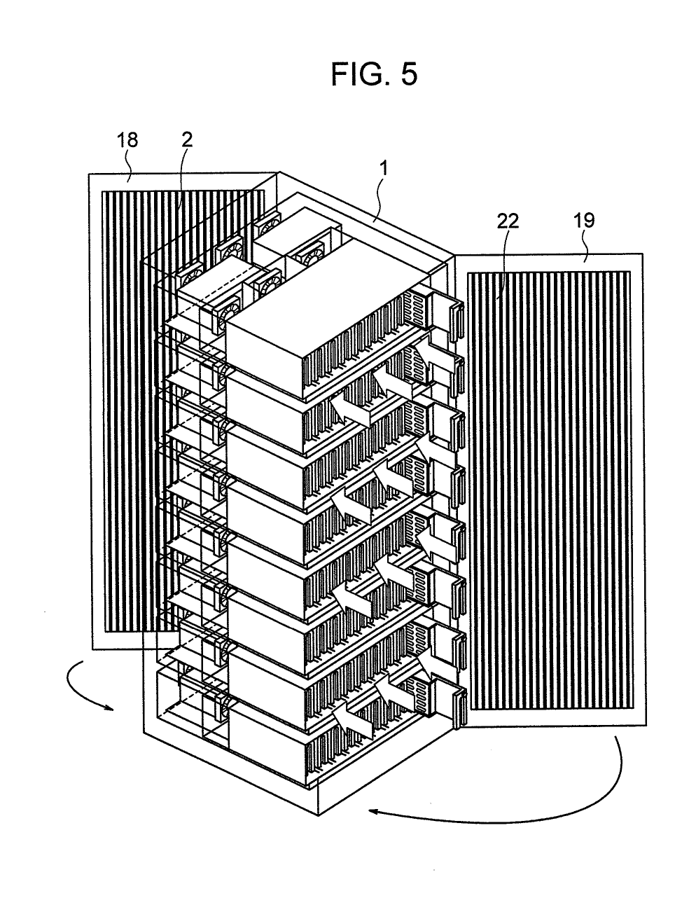

A third embodiment of the present invention is shown in FIG. 4 and FIG. 5.

FIG. 4 is a configuration diagram of a disk array apparatus and electronic equipment system of this embodiment.

In FIG. 4, the disk array apparatus and electronic equipment system are constructed of an apparatus housing 1 which is the disk array apparatus or electronic equipment, a vapor compression cycle 100, a hot water tank 6 and an absorption cycle 200 or the like.

The vapor compression cycle 100 is constructed of an air source evaporator 2, a compressor 3, a water heat source condenser 4 and an expansion valve 5 or the like. Chlorofluorocarbon alternatives such as R410A or a natural refrigerant such as CO₂ are used as a refrigerant. Furthermore, the absorption cycle 200 is constructed of a generator 9, a condenser 10, an evaporator 11, an absorber 12 and a solution pump 13 or the like. A natural refrigerant such as water is used as a refrigerant and lithium bromide or the like is used as a solution.

In FIG. 4, reference numerals common to those described in FIG. 1 and FIG. 3 denote the same components, and therefore explanations thereof are omitted.

In this embodiment, the vapor compression cycle 100, hot water tank 6 and absorption cycle 200 are installed as separate units in the vicinity of the apparatus housing 1.

In FIG. 4, cooled air driven by a fan inside the apparatus housing 1 flows into the apparatus housing 1, cools down each heat generating part and is then exhausted from behind the apparatus housing 1. This is because when an electronic apparatus is mounted in a 19-inch standard rack, the wiring space of the rack is normally used as an exhaust area of the entire rack.

FIG. 5 is a perspective view of a disk array apparatus and electronic equipment provided with this embodiment.

In FIG. 5, the apparatus housing 1 of this embodiment is constructed of a plurality of disk array apparatuses or electronic equipment units mounted in the 19-inch standard rack. A back door 18 with the air source evaporator 2 incorporated is provided on the exhaust side of the apparatus housing 1. Furthermore, a front door 19 with an air source water heat exchanger 22 incorporated is provided on the air intake side of the apparatus housing 1.

According to this embodiment, the vapor compression cycle 100 is operated using waste heat of 40, 50° C. exhausted from behind the aforementioned apparatus housing 1 as a heat source on the low-temperature side. This causes the exhaust air from the apparatus housing 1 to be cooled down to on the order of a room temperature and emitted into ambient air, and can thereby drastically reduce the load on the air conditioner for cooling waste heat from the apparatus housing 1, which is conventionally required. Alternatively, the air conditioner can be omitted.

This is especially effective in reducing the load on the air conditioner when many apparatus housings 1 such as a data center are installed densely.

On the other hand, in the vapor compression cycle 100, the refrigeration cycle operates using waste heat of 40° C. to 50° C. of the apparatus housing 1 as the heat source on the low-temperature side as described above and heat resulting from adding the heat generated from the compressor 3 to the absorbed heat (cooled heat) from the waste heat from the air source evaporator 2 is emitted to the water side of the water heat source condenser 4. This causes the temperature of the water side to rise to around 90° C. at the outlet of the water heat source condenser 4. On a water pipe 15 side, water is circulating by the function of a hot water pump 7 and hot water of a high temperature obtained from the water heat source condenser 4 is stored in the hot water tank 6.

This embodiment allows the entire system to realize energy saving by recovering energy of hot water stored in the hot water tank 6.

That is, this embodiment operates the absorption cycle 200 using hot water around 90° C. stored in the hot water tank 6 as a heat source, and can thereby generate cold water. This embodiment causes the generator 9 to generate vapor through a water/solution heat exchanger 8 installed in the generator 9. Vapor is converted to liquid in the condenser 10 and then evaporated at the evaporator 11 to generate cold water.

Thus, the present invention can recover waste heat of 50 to 60° C. exhausted from the electronic apparatus or the like which is not conventionally used, and can thereby drastically improve the energy efficiency as the system. Furthermore, the cold water generated is transported to an air source water heat exchanger 22 through a cold water pump 21 on the cold water pipe 17 side and used to reduce the temperature of air taken into the apparatus housing 1.

The ability to reduce the temperature of air taken into the apparatus housing 1 as in this embodiment allows each electronic part to be cooled satisfactorily with a small amount of air, and thereby allows the apparatus system to operate with low noise. Alternatively, this also allows high density mounting without increasing the amount of air of the fan in the apparatus housing 1 and contributes to improvement of performance of the apparatus.

### Embodiment 4

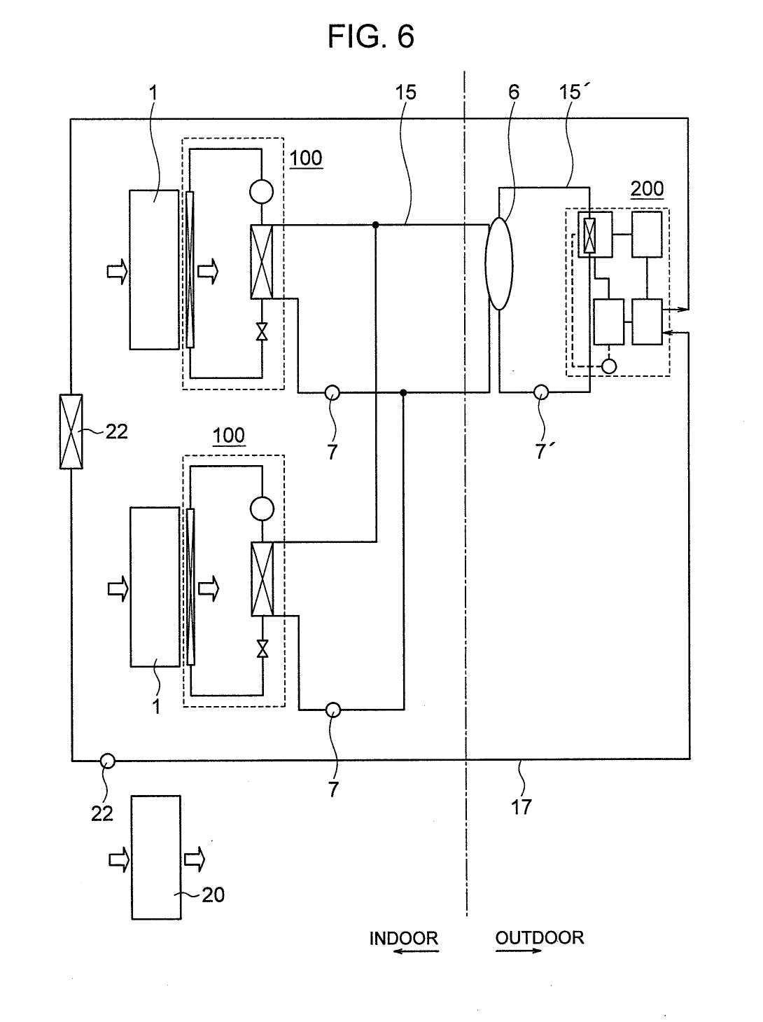

A fourth embodiment of the present invention is shown in FIG. 6.

FIG. 6 is a configuration diagram of a disk array apparatus and electronic equipment system of this embodiment.

In FIG. 6, this system is constructed of an apparatus housing 1 which is the disk array apparatus or electronic equipment, a vapor compression cycle 100, a hot water tank 6 and an absorption cycle 200 or the like.

In this embodiment, a plurality of apparatus housings 1 are installed indoors in a data center or the like and the vapor compression cycle 100 is installed in the vicinity of the apparatus housing 1 as a separate unit. Furthermore, the hot water tank 6 and absorption cycle 200 common to the plurality of apparatus housings 1 are installed outdoors.

In FIG. 6, cooled air driven by a fan inside the apparatus housing 1 flows into the apparatus housing 1, cools down each heat generating part and is then exhausted from behind the apparatus housing 1. This is because when an electronic apparatus is mounted in a 19-inch standard rack, the wiring space of the rack is normally used as an exhaust area of the entire rack. The apparatus housing 1, which is the disk array apparatus and electronic equipment of this embodiment, is constructed of a plurality of disk array apparatuses or electronic equipment units mounted in the 19-inch standard rack. Furthermore, a back door 18 with the air source evaporator 2 incorporated is provided on the exhaust side of the apparatus housing 1.

According to this embodiment, the vapor compression cycle 100 is operated using waste heat of 40, 50° C. exhausted from behind the aforementioned apparatus housing 1 as a heat source on the low-temperature side. This causes the exhaust air from the apparatus housing 1 to be cooled down to on the order of a room temperature and emitted into ambient air. This can drastically reduce the load on the air conditioner for cooling waste heat from the apparatus housing 1, which is conventionally required or the air conditioner can be omitted. This is especially effective in reducing the load on the air conditioner when many apparatus housings 1 such as a data center are installed densely.

On the other hand, in the vapor compression cycle 100, the refrigeration cycle operates using waste heat of 40° C. to 50° C. of the apparatus housing 1 as the heat source on the low-temperature side as described above and heat resulting from adding the heat generated from a compressor 3 to the absorbed heat (cooled heat) from the waste heat from an air source evaporator 2 is emitted to the water side of a water heat source condenser 4. This causes the temperature of the water side to rise to around 90° C. at the outlet of the water heat source condenser 4. On a water pipe 15 side, hot water is circulating by the function of a hot water pump 7 and hot water at a high temperature obtained from the water heat source condenser 4 is stored in the hot water tank 6.

This embodiment allows the entire system to realize energy saving by recovering the energy of hot water stored in the hot water tank 6. That is, this embodiment operates the absorption cycle 200 using hot water around 90° C. stored in the hot water tank 6 as a heat source, and can thereby generate cold water. This embodiment causes the generator 9 to generate vapor through a water/solution heat exchanger 8 installed in the generator 9. Vapor is converted to liquid in a condenser 10 and then evaporated at the evaporator 11 to generate cold water.

Thus, the present invention can recover waste heat of 50 to 60° C. exhausted from the electronic apparatus or the like which is not conventionally used, and can thereby drastically improve the energy efficiency as the system.

According to this embodiment, the cold water generated is transported to an air source water heat exchanger 22 through a cold water pump 21 on a cold water pipe 17 side and used to reduce the temperature of air taken into the apparatus housing 1. A plurality of other electronic equipment units 20 are provided in the room in addition to the plurality of apparatus housings 1 and the cold water generated contributes to cooling of waste heat exhausted from the other electronic equipment units 20. Therefore, the air conditioning load in a large space such as a data center can be drastically reduced. Furthermore, the ability to reduce the temperature of air taken into the apparatus housing 1 or other electronic equipment 20 allows each electronic part to be cooled satisfactorily with a small amount of air, and thereby allows the apparatus system to operate with low noise. Alternatively, this also allows high density mounting without increasing the amount of air of the fan in the apparatus housing 1 or other electronic equipment 20 and contributes to improvement of performance of the apparatus.

As described above, in a space of a data center or the like where many disk array apparatuses and electronic equipment systems are arranged, the present invention can reduce the energy required for cooling the apparatus itself and cooling the space, drastically improve processing speed and reliability of the apparatus/system and realize capacity and speed enhancements. Furthermore, the present invention can realize a low-noise disk array apparatus and electronic equipment system.

It should be further understood by those skilled in the art that although the foregoing description has been made on embodiments of the invention, the invention is not limited thereto and various changes and modifications may be made without departing from the spirit of the invention and the scope of the appended claims.

1. An electronic equipment system comprising:
a chassis,
a plurality of disk-drives contained by the chassis,
a controller for controlling the disk-drives, including an element for generating a heat energy,
a refrigeration cycle for increasing a temperature of the heat energy generated by the element,
a hot-water tank for absorbing the heat energy whose temperature is increased by the refrigeration cycle, and
an absorption chiller cycle.

2. The electronic equipment system according to claim 1, wherein the refrigeration cycle includes a compressor, a radiator, an expansion valve, an evaporator and a pipe arrangement for connecting the compressor, radiator, expansion valve and evaporator to absorb at the evaporator the heat energy generated by the element.

3. The electronic equipment system according to claim 2, wherein the radiator of the refrigeration cycle is thermally connected to the hot-water tank.

4. The electronic equipment system according to claim 1, wherein the absorption chiller cycle is connected to the hot-water tank so that the heat energy is absorbed by the absorption chiller cycle from the hot-water tank.

5. The electronic equipment system according to claim 1, wherein the absorption chiller cycle is arranged to absorb the heat energy to supply a cold water to a building containing at least a part of the electronic equipment system.

6. An electronic equipment system comprising:
an electric equipment including at least one of a heat generating element such as CPU and a disk array device including a plurality of disk-drives and a controller for controlling the disk-drives,
a vapor compression cycle for absorbing a waste heat energy of relatively low temperature generated as a relatively low temperature heat source by the electric equipment to output a water of relatively high temperature, and
an absorption chiller cycle for using the water of relatively high temperature as a heat source for the absorption chiller cycle to recover the waste heat energy.

7. An electronic equipment system comprising:
an electric equipment including at least one of a heat generating element such as CPU and a disk array device including a plurality of disk-drives and a controller for controlling the disk-drives,
a rear door arranged at an air-exhaust side of the electric equipment and including an air source evaporator, and
a front door arranged at an air-intake side of the electric equipment and including an air source water-air heat exchanger.
